(19) United States
(12) Patent Application Publication
(10) Pub. No.: US 2017/0229426 A1
(43) Pub. Date: Aug. 10, 2017

(54) FAN-OUT BACK-TO-BACK CHIP STACKED PACKAGES AND THE METHOD FOR MANUFACTURING THE SAME

(71) Applicant: POWERTECH TECHNOLOGY INC., Hsinchu (TW)

(72) Inventors: Ching Wei HUNG, Hsinchu (TW); Wen-Jeng FAN, Hsinchu (TW)

(21) Appl. No.: 15/277,349

(22) Filed: Sep. 27, 2016

(30) Foreign Application Priority Data
Feb. 5, 2016 (TW) 105104146

(51) Int. Cl. H01L 25/065; H01L 25/00; H01L 23/538; H01L 23/00; H01L 21/56; H01L 21/48

(52) U.S. Cl. CPC H01L 25/0657; H01L 21/561; H01L 21/486; H01L 23/5384; H01L 23/5389; H01L 24/20; H01L 24/96; H01L 25/50; H01L 24/02; H01L 24/04; H01L 24/13; H01L 24/19; H01L 25/0652; H01L 24/73; H01L 2021/60015

(57) ABSTRACT

Disclosed is a fan-out back-to-back chip stacked package, comprising a back-to-back stack of a first chip and a second chip, an encapsulant, a plurality of vias disposed in the encapsulant, a first redistribution layer and a second redistribution layer. The encapsulant encapsulates the sides of the first chip and the sides of the second chip simultaneously and has a thickness not greater than the chip stacked height to expose a first active surface of the first chip and a second active surface of the second chip. The encapsulant has a first peripheral surface expanding from the first active surface and a second peripheral surface expanding from the second active surface. The first redistribution layer is formed on the first active surface and extended onto the first peripheral surface to electrically connect the first chip to the vias in the encapsulant. The second RDL is formed on the second active surface and extended onto the second peripheral surface to electrically connect the second chip to the vias in the encapsulant. Accordingly, the structure realizes a thin package configuration of multi-chip back-to-back stacking to reduce package warpage.

### FIELD OF THE INVENTION

The present invention relates to a semiconductor package and more specifically to a fan-out back-to-back chip stacked package and the method for manufacturing the same.

### BACKGROUND OF THE INVENTION

Due to the mismatch of Thermal Expansion Coefficients (CTE) among different packaging materials in a semiconductor package, package warpage caused by thermal stress is always a severe issue. In a conventional chip stacked package, a plurality of semiconductor chips with smaller thermal expansion coefficients are vertically stacked on a printed circuit board with a larger thermal expansion coefficient leading to an even worse package warpage issue.

Recently, a Fan-Out Wafer-Level Package (FOWLP) and Fan-Out Panel-Level Package (FOPLP) are proposed by implementing a Wafer Support System (WSS) or a Panel Support System (PSS) as a temporary carrier during packaging processes. The formed redistribution layers serve as chip signal extension and the temporary carrier is removed at the end of the packaging processes so that conventional substrate for BGA package can be eliminated to achieve thinner packages with finer pitches and larger circuit density. The impact of the package warpage is reduced through elimination of the substrate is reduced, however, the reduction of mold thickness and the large molding area of wafer-level process or panel-level molding process may cause a wafer warpage or panel warpage issue during the singulation process performed after the temporary carrier removal process

### SUMMARY OF THE INVENTION

The main purpose of the present invention is to provide a fan-out back-to-back chip stacked package and the method for manufacturing the same to realize structure balance of a fan-out back-to-back chip stacked package without a substrate and to achieve thinner chip stacked package without the impact of package warpage in wafer-level or panel-level molding processes.

The other purpose of the present invention is to provide a fan-out back-to-back chip stacked package and the method for manufacturing the same having the advantages of one-time molding process and one-time double-side redistribution layer (RDL) electroplating process to reduce the manufacturing steps of fan-out packages.

According to the present invention, a fan-out back-to-back chip stacked package is revealed comprising a first chip, a second chip, an encapsulant, a via, a first redistribution layer and a second redistribution layer. The first chip has a first active surface, a first back surface opposing to the first active surface, and a plurality of first sides. A plurality of first bonding pads are disposed on the first active surface. The second chip has a second active surface, a second back surface opposing to the second active surface and a plurality of second sides. A plurality of second bonding pads are disposed on the second active surface. The second chip is stacked on the first chip. Therein, a die-attach film layer is disposed between the first back surface and the second back surface. There is a chip stacked height formed from the first active surface to the second active surface. The encapsulant encapsulates the first sides of the first chip and the second sides of the second chip simultaneously. The thickness of the encapsulant is not greater than the chip stacked height. The first active surface and the second active surface are respectively exposed from two opposing faces of the encapsulant. The encapsulant has a first peripheral surface expanding from the first active surface and a second peripheral surface expanding from the second active surface. The vias are disposed in the encapsulant. Each via has a first terminal and a second terminal. Therein, the first terminals are exposed from the first peripheral surface of the encapsulant and the second terminals are exposed from the second peripheral surface of the encapsulant. The first redistribution layer is formed on the first active surface and extended onto the first peripheral surface to electrically connect the first bonding pads to the corresponding first terminals of the vias. The second redistribution layer is formed on the second active surface and extended onto the second peripheral surface to electrically connect the second bonding pads to the corresponding second terminals.

### DESCRIPTION OF THE DRAWINGS

FIG. 1 is a cross-sectional view of a fan-out back-to-back chip stacked package according to the first embodiment of the present invention.

FIG. 2 is an illustration of a wafer map for the fan-out back-to-back chip stacked package according to the first embodiment of the present invention.

FIG. 3 is a flowchart of a manufacturing method of the fan-out back-to-back chip stacked package according to the first embodiment of the present invention.

FIGS. 4A to 4I are component cross-sectional views illustrating the primary packaging steps during the manufacture process of the fan-out back-to-back chip stacked package according to the first embodiment of the present invention.

FIG. 5 is a cross-sectional view of another fan-out back-to-back chip stacked package according to the second embodiment of the present invention.

### DETAILED DESCRIPTION OF THE INVENTION

With reference to the attached drawings, the present invention is described by means of the embodiment(s) below where the attached drawings are simplified for illustration purposes only to illustrate the structures or methods of the present invention by describing the relationships between the components and assembly in the present invention. Therefore, the components shown in the figures are not expressed with the actual numbers, actual shapes, actual dimensions, nor with the actual ratio. Some of the dimensions or dimension ratios have been enlarged or simplified to provide a better illustration. The actual numbers, actual shapes, or actual dimension ratios can be selectively designed and disposed and the detail component layouts may be more complicated.

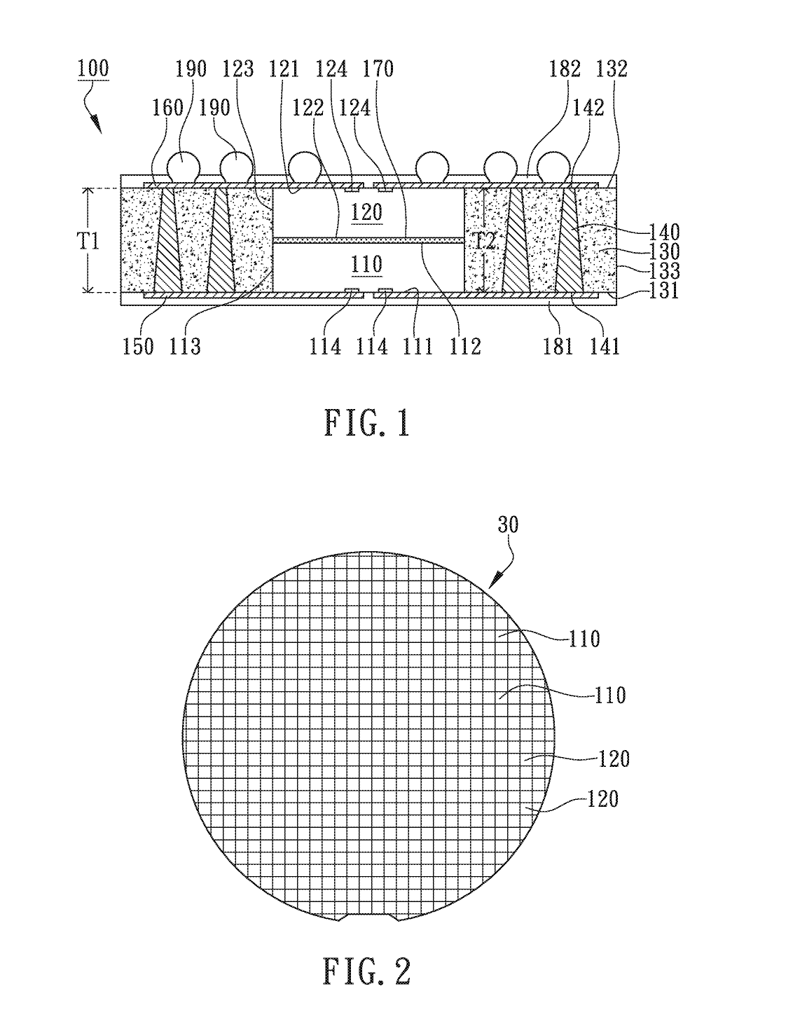

According to the first embodiment of the present invention, a cross-sectional view of a fan-out back-to-back chip stacked package 100 is illustrated in FIG. 1 and a wafer map is illustrated in FIG. 2. A fan-out back-to-back chip stacked package 100 comprises a first chip 110, a second chip 120, an encapsulant 130, a plurality of vias 140, a first redistribution layer 150 and a second redistribution layer 160.

As shown in FIG. 1, the first chip 110 has a first active surface 111, a first back surface 112 opposing to the first active surface 111 and a plurality of first sides 113. A plurality of bonding pads 114 are disposed on the first active surface 111. The material used to form the first chip 110 is semiconductor material. And, an integrated circuit is fabricated. The first bonding pads 114 on the first active surface 111 are the connection terminals of the integrated circuit. Normally, the first back surface 112 is an opposing surface parallel to the first active surface 111. The first sides 113 are perpendicular to the first active surface 111 and to the first back surface 112.

The second chip 120 has a second active surface 121, a second back surface 122 opposing to the second active surface 121 and a plurality of second sides 123. A plurality of second bonding pads 124 are disposed on the second active surface 121. The second chip 120 and the first chip 110 are stacked to each other. There is a chip stacked height T2 formed from the first active surface 111 to the second active surface 121. This means that the chip stacked height T2 is equal to the vertical distance between the first active surface 111 and the second active surface 121. The material used to form the second chip 120 is also semiconductor material. And, another integrated circuit is fabricated. The second bonding pads 124 on the second active surface 121 are connection terminals of the integrated circuit. Normally the second back surface 122 is an opposing surface parallel to the second active surface 121. In some embodiments, the first chip 110 and the second chip 120 are identical chips. As shown in FIG. 2, the first chip 110 and the second chip 120 can be picked from the same wafer 30 or from the Known Good Die (KGD) of the same wafer.

A die-attach film layer 170 is disposed between the first back surface 112 and the second back surface 122. Preferably, the die-attach film layer 170 is disposed at a center line between a first peripheral surface 131 and a second peripheral surface 132 of the encapsulant 130 to function as an intermediate buffer layer to achieve structure balance for better package warpage resistance. The chip stacked height T2 of the first chip 110 and the second chip 120 may be greater than the total thickness of the first chip 110 and the second chip 120 because of the die-attach film layer 170.

The encapsulant 130 encapsulates the first sides 113 of the first chip 110 and the second sides 123 of the second chip 120 simultaneously. Therein, the thickness T1 of the encapsulant 130 is not greater than the chip stacked height T2 of the first chip 110 and the second chip 120 in a manner that the first active surface 111 and the second active surface 121 are respectively exposed from two opposing faces of the encapsulant 130. In other words, the encapsulant 130 does not encapsulate the first active surface 111 nor the second active surface 121, the first active surface 111 and the second active surface 121 are exposed. The encapsulant 130 may be a single layer of molding compound having a substrate profile. In the exemplary embodiment, the thickness T1 of the encapsulant 130 is equal to the chip stacked height T2 of the first chip 110 and the second chip 120. Moreover, the encapsulant 130 has a first peripheral surface 131 expanding from the first active surface 111 and a second peripheral surface 132 expanding from the second active surface 121. The encapsulant 130 is a thermosetting molding compound used to encapsulate the chips 110 and 120. The thermosetting molding compound may comprise Epoxy Resin, Silicon Resin, or Polyimide Resin, etc. The first active surface 111 and the first peripheral surface 131 may be coplanar or with a small mold height difference. The second active surface 121 and the second peripheral surface 132 may be coplanar or with a small mold height difference.

The vias 140 are disposed in the encapsulant 130. Each via 140 has a first terminal 141 and a second terminal 142. Each via 140 is formed on a through hole in the encapsulant 130. The first terminals 141 are exposed on the first peripheral surface 131 and the second terminals 142 are exposed on the second peripheral surface 132. In the present embodiment, the vias 140 can be shaped as half cones. Preferably, the surface area of the first terminals 141 exposed in the first peripheral surface 131 is greater than the surface area of the second terminals 142 exposed in the second peripheral surface 132. Conductive material is filled into the vias 140 to completely fill the vias 140 or just disposed on the sidewalls of the vias 140. Therefore, the vias 140 can replace the Through-Silicon Via (TSV) which penetrating through chips.

The first redistribution layer 150 is formed on the first active surface 111 and extended onto the first peripheral surface 131 to electrically connect the first bonding pads 114 to the corresponding first terminals 141. The second redistribution layer 160 is formed on the second active surface 121 and extended onto the second peripheral surface to electrically connect the second bonding pads 124 to the corresponding second terminals 142. Therefore, the vias 140 electrically connect the first redistribution layer 150 to the second redistribution layer 160 to make the fan-out back-to-back chip stacked package 100 have a double-side electrical connection. The first redistribution layer 150 and the second redistribution layer 160 are fabricated by semiconductor equipment of deposition, electroplating and etching which are quite different from the manufacturing processes of conventional substrate circuitry. The first redistribution layer 150 and the second redistribution layer 160 may be formed by stacking multiple metals, i.e. Titanium/Copper/Copper (Ti/Cu/Cu), Titanium/Copper/Copper/Nickel/Gold (Ti/Cu/Cu/ Ni/Au) etc.

A fan-out back-to-back chip stacked package 100 may further comprise a first passivation layer 181 and a second passivation layer 182. The first passivation layer 181 is formed over the first active surface 111 as well as over the first peripheral surface to cover the first redistribution layer 150. And, the second passivation layer 182 is formed over the second active surface 121 as well as over the second peripheral surface 132 to cover the second redistribution layer 160. The first passivation layer 181 may conform to the surface contour of the encapsulant 130, the first chip 110, and the first redistribution layer 150. Thus, the circuitry of the first redistribution layer 150 may be fully covered and protected. The second passivation layer 182 may conform to the surface contour of the encapsulant 130, the second chip 120, and the second distribution layer 160. Thus, the circuitry of the second redistribution layer 160 may be fully covered and protected. The material used to form the first passivation 181 and the second passivation layer 182 may be organic isolation layers such as Polyimide. The thickness of the first passivation layer 181 and the second passivation layer 182 may approximately be 5 μm. Furthermore, a plurality of solder balls 190 may be disposed on the second redistribution layer 160, however, in a different embodiment, the solder balls 190 may be disposed on the first redistribution layer 150.

Therefore, the fan-out back-to-back chip stacked package 100 according to the present invention realizes a structurally balanced multi-chip fan-out back-to-back chip stacked package without substrate to achieve thinner package without the impact of package warpage.

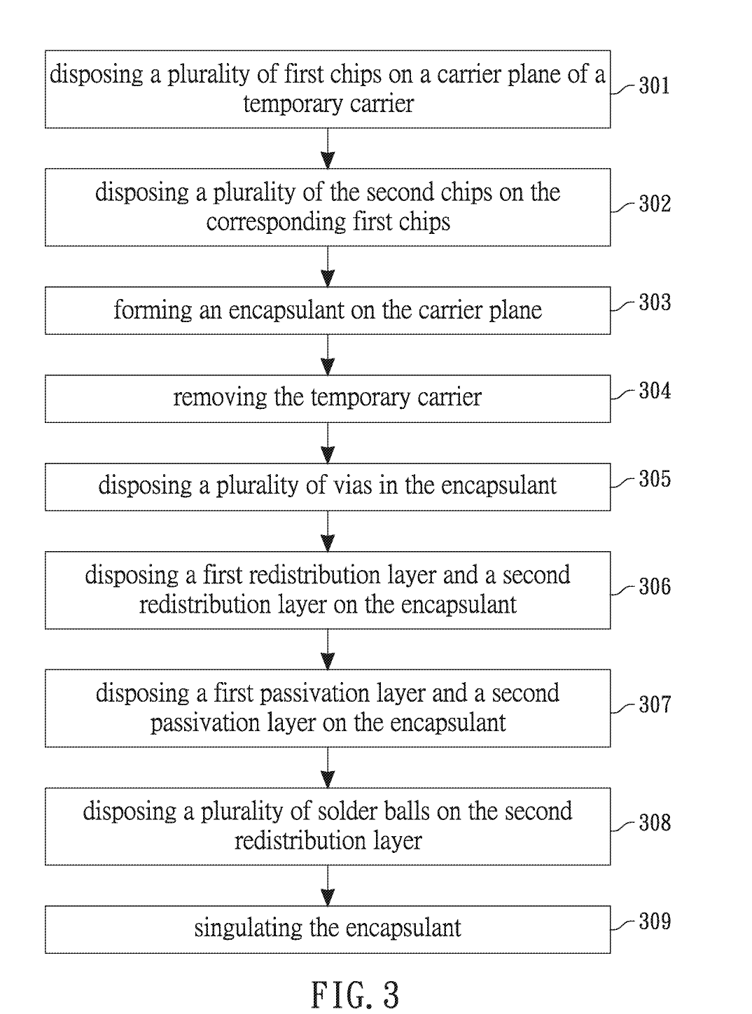

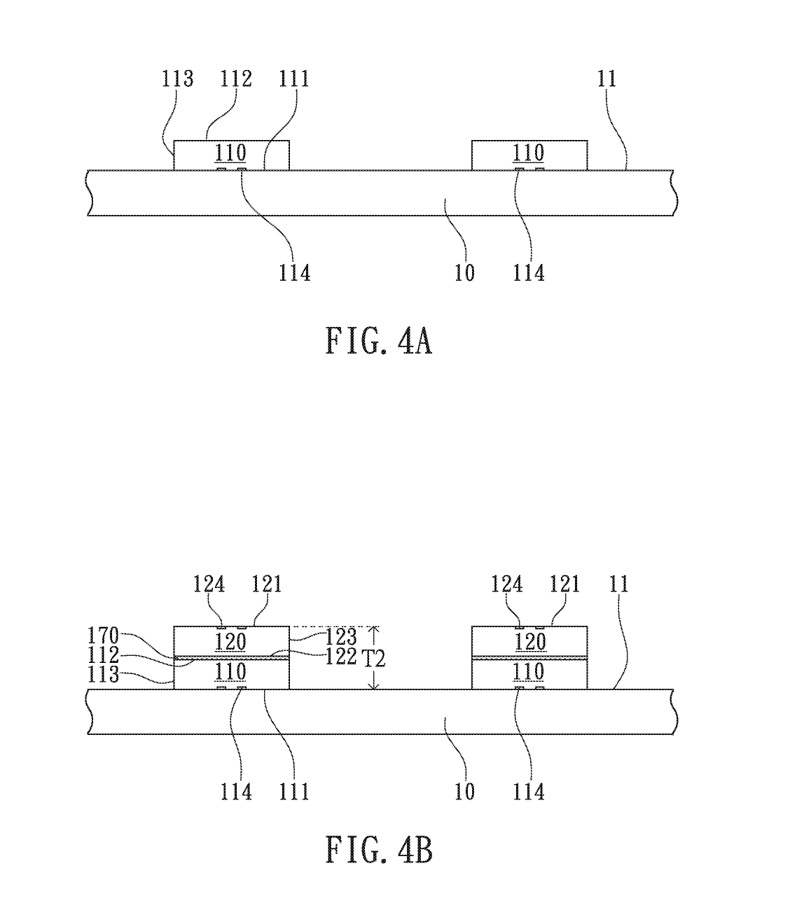

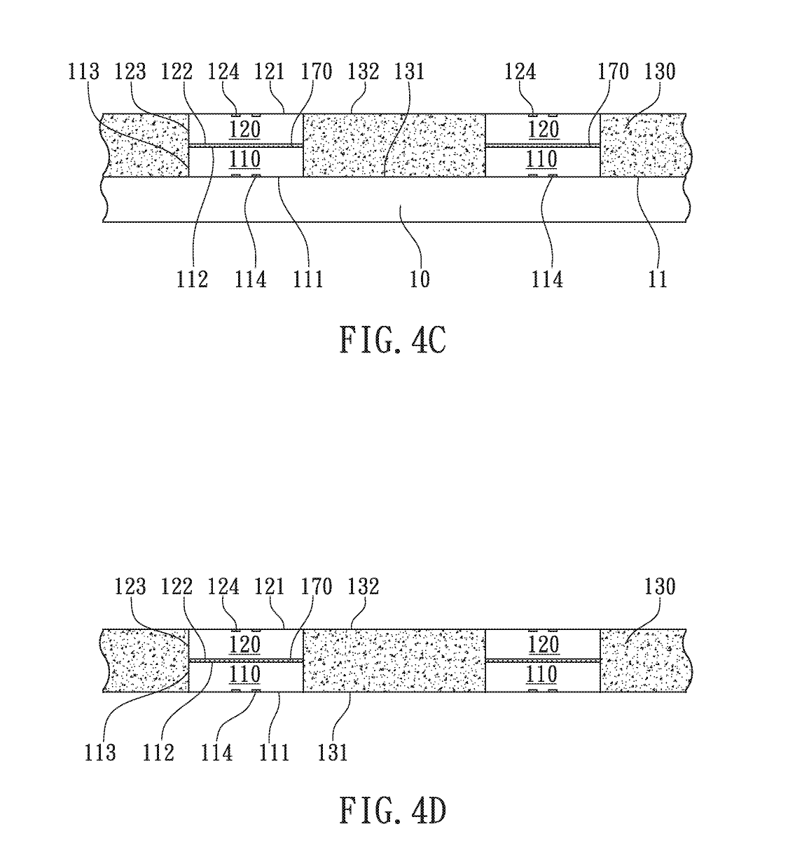

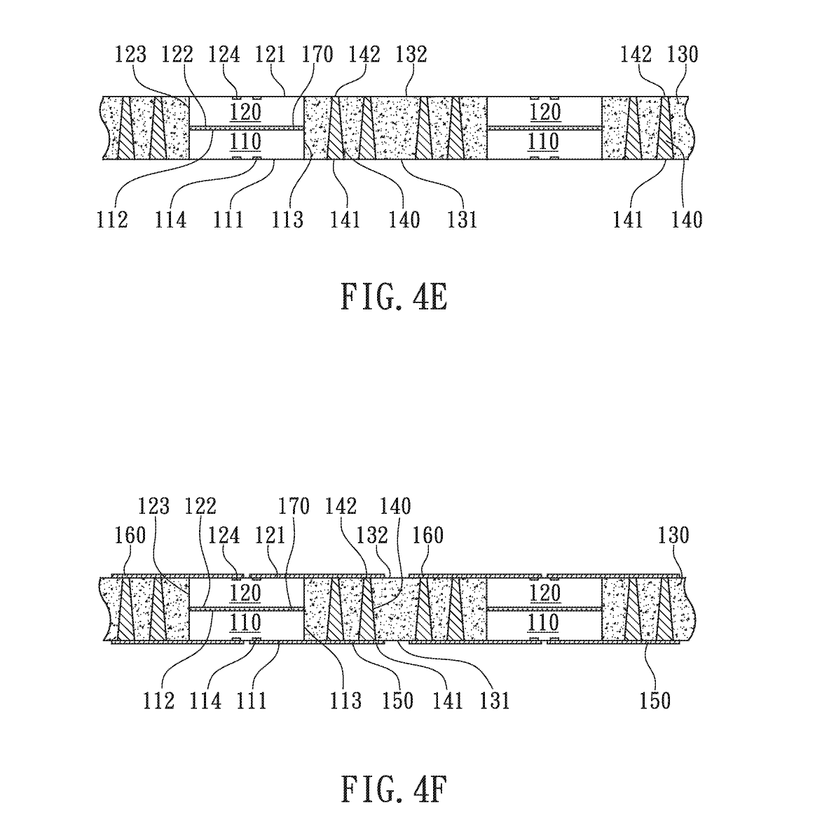

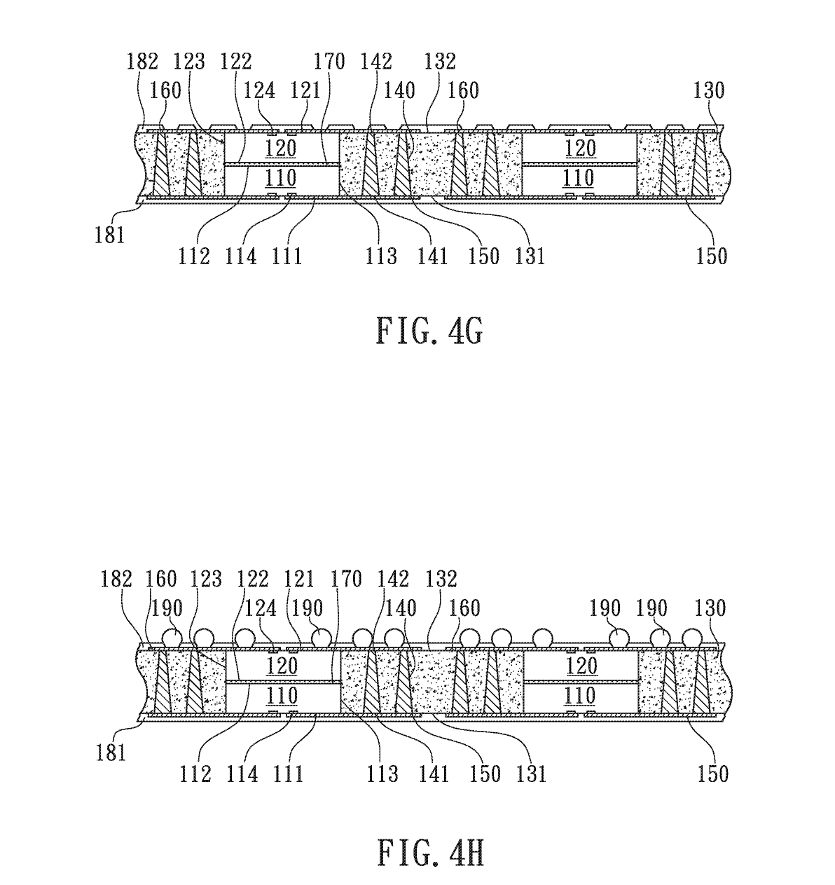

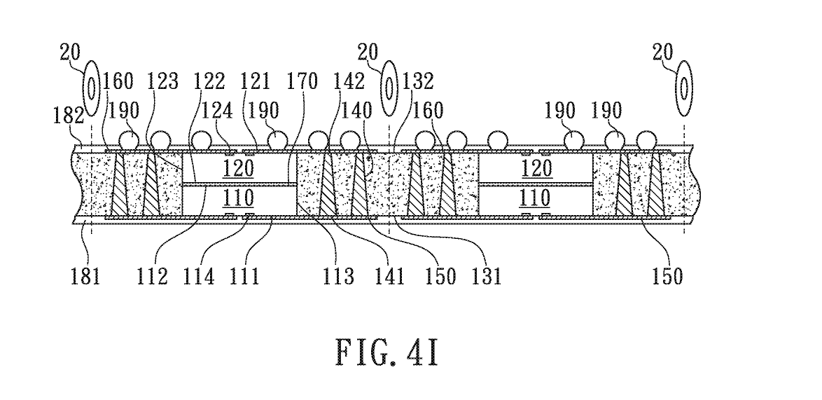

The manufacturing method of the above-mentioned fan-out back-to-back chip stacked package 100 is further described in detail as follows. FIG. 3 illustrates a flowchart of the method. FIGS. 4A to 4I are component cross-sectional views illustrating each primary packaging process during the fabrication of the fan-out back-to-back chip stacked package.

The method comprises the steps as below:

Step 301: disposing a plurality of first chips on a carrier plane of a temporary carrier;
Step 302: disposing a plurality of the second chips on the corresponding first chips;
Step 303: forming an encapsulant on the carrier plane;
Step 304: removing the temporary carrier;
Step 305: disposing a plurality of vias in the encapsulant;
Step 306: disposing a first redistribution layer and a second redistribution layer on the encapsulant;
Step 307: disposing a first passivation layer and a second passivation layer on the encapsulant;
Step 308: disposing a plurality of solder balls on the second redistribution layer; and
Step 309: singulating the encapsulant.

In step 301, as shown in FIG. 4A, a plurality of first chips 110 are disposed on a carrier plane 11 of a temporary carrier 10. Each first chip 110 has an active surface 111, a back surface 112 and a plurality of first sides 113. Therein, a plurality of first bonding pads 114 are disposed on each first active surface 111. The temporary carrier 10 may be a wafer or a panel having a layer of adhesive. In some embodiments, the layer of adhesive may be a peelable adhesive. In the present step, the first chips 110 may be disposed on the carrier plane 11 by pick-and-place process with the first active surfaces 111 adhering to the temporary carrier 10.

In step 302, as shown in FIG. 4B, a plurality of the second chips 120 are vertically stacked on the corresponding first chips 110. Each second chip 120 has a second active surface 121, a back surface 122 and a plurality of second sides 124. Therein, a plurality of second bonding pads 124 are disposed on each second active surface 121. A die-attach film layer 170 is disposed between the first back surface 112 and the corresponding second back surface 122. There is a chip stacked height T2 formed from the first active surfaces 111 to the second active surfaces 121. In the present step, the second back surfaces 122 of the second chips 120 are attached to the corresponding first back surfaces 112. Referring to the FIG. 2 again, at least a wafer 30 is singulated into a plurality of individual chips to provide the first chips 110 and the second chips 120.

In step 303, as shown in FIG. 4C, an encapsulant 130 is formed on the carrier plane 11 of the temporary carrier 10. The encapsulant 130 encapsulates the first sides 113 of the first chips 110 and the second sides 123 of the second chips 120 simultaneously. The encapsulant may be formed using a one-time molding process. The encapsulant 130 may be a single layer of molding compound having a substrate profile in wafer or panel form. Preferably, the thickness T1 of the encapsulant 130 is not greater than the chip stacked height T2 in a manner that the first active surface 111 and the second active surface 121 are respectively exposed from two opposing faces of the encapsulant 130. Corresponding to each chip stacked package, the encapsulant 130 has a first peripheral surface 131 expanding from the first active surface 111 and a second peripheral surface 132 expanding from the second active surface 121. The above-mentioned “one-time molding” means that the encapsulant 130 is formed with only one molding process to form a single-layer structure in a wafer form or in a panel form.

In step 304, as shown in FIG. 4D, the temporary carrier 10 is removed to expose the first active surfaces 111 of the first chips 110 and the first peripheral surfaces 131 of the encapsulant 130. The temporary carrier 10 may be removed by UV radiation to remove adhesion. The structures may be vertically symmetrical because of the die-attach film layer 170. Since a plurality of double-chip back-to-back chip stacked structures are assembled in the encapsulant 130 and the structures are vertically symmetrical, therefore, the encapsulant 130 is in perfect stress balance. Even without the support of the temporary carrier 10, the encapsulant 130 either in wafer form or in panel form does not encounter warpage nor deformation which will greatly hinder the following fan-out wafer packaging processes. Thus, a one-time double-side redistribution-layer electrical-plating process may be implemented.

In step 305, in FIG. 4E, a plurality of vias 140 are disposed in the encapsulant 130 using the existing via formation technology after the temporary carrier 10 is removed without wafer/panel level warpage because of double sided stress balance. Each via 140 has a first terminal 141 exposed from the first peripheral surface 131 and a second terminal 142 exposed from the second peripheral surface 132. The formation of the vias 140 may be done using drilling processes and/or through-hole electroplating processes.

In step 306, as shown in FIG. 4F, the first redistribution layer 150 and the second redistribution layer 160 are formed by one-time double-side RDL electrical-plating processes. The first redistribution layer 150 is formed on the first active surface 111 and extended onto the first peripheral surface 131 to electrically connect the first bonding pads 114 to the corresponding first terminals 141. And, the second redistribution layer 160 is formed on the second active surface 121 and extended onto the second peripheral surface 132 to electrically connect the second bonding pads 124 to the corresponding second terminals 142. Furthermore, the seed layer for the first redistribution layer 150, the seed layer for the second redistribution layer 160, and the corresponding patterned photoresist layers are individually formed on different surfaces of the encapsulant 130. The encapsulant 130 is disposed into the electroplating tank to perform the one-time double-side electroplating process. When electroplating, the encapsulant 130 is fixed in a double-sided hollow fixing ring. The patterned photoresist layer and the exposed seed layers are removed after the electroplating process. Therefore, the redistribution layers 150, 160, are formed simultaneously using double-side electrical-plating process. The redistribution layers 150, 160 may have the same structures, materials and thicknesses.

In step 307, as shown in FIG. 4G a first passivation layer 181 and a second passivation layer 182 are formed after the fabrication processes of the first redistribution layer 150 and the second redistribution layer 160. The first passivation layer 181 is formed over the first active surfaces 111 as well as over the first peripheral surface 131 to cover the first redistribution layer 150. The second passivation layer 182 is formed over the second active surfaces 121 as well as over the second peripheral surfaces 132 to cover the second redistribution layer 160. The first passivation layer 181 and the second passivation layer 182 are formed by one-time double-side deposition process or by multiple one-side deposition process. For example, the encapsulant 130 can be fixed on a hollow fixing ring. An uncured protective layer is individually formed over the top face of the encapsulant 130 and another uncured protective layer is individually formed over the bottom face of the encapsulant 130 by one-time spin coating processes to reduce the thickness of the uncured protective layers. After double-side curing process and single-side lithographic process, one-time double-side deposition of the first passivation layer 181 and the second passivation layer 182 can be achieved. Therein, the first passivation layer 181 and the second passivation layer 182 can have the same structures, materials and thicknesses. The external ball pads of the second redistribution layer 160 are exposed from the patterned opening of the second passivation layer 182.

In step 308, as shown in FIG. 4H, a plurality of solder balls 190 are disposed on the second redistribution layer 160 after the fabrication process of the first redistribution layer 150 and the second redistribution layer 160. The solder balls 190 are disposed at appropriate locations on the second redistribution layer 160 by ball placement process or by reflowing process of solder paste deposition.

In step 309, as shown in FIG. 4I, the encapsulant 130 is singulated to form a plurality of individual fan-out back-to-back chip stacked packages 100. The singulation process may use a blade of a sawing tool 20 to cut through the scribe lines of the encapsulant 130 and penetrate through the encapsulant 130 from the first peripheral surfaces 131 to the second peripheral surfaces 132. Normally singulation process of the encapsulant 130 can be done by package saw, laser cutting, etching, or combination of above-mentioned processes.

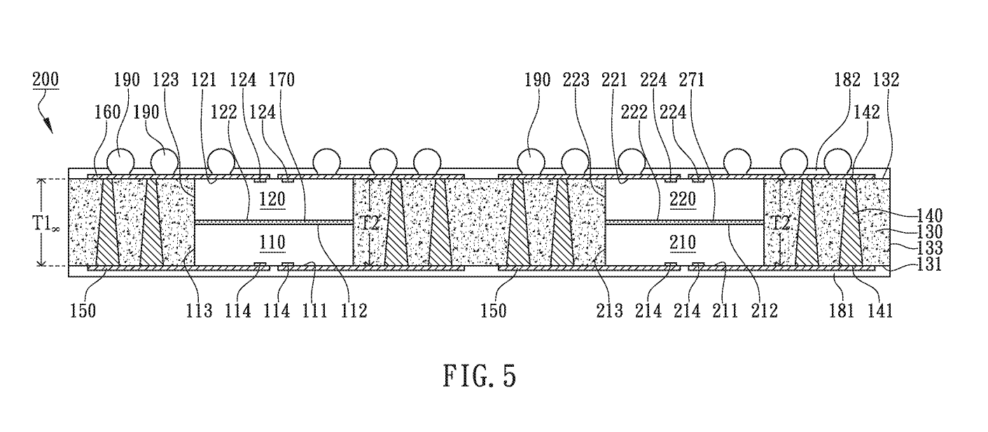

According to the second embodiment of the present invention, a cross-sectional view of another fan-out back-to-back chip stacked package 200 is illustrated in FIG. 5. The major components may have the same names and functions as that of the first embodiment. Thus, it will no longer be discussed for brevity. The fabrication process of the second embodiment are generally the same as described from FIG. 4A to FIG. 4I in the first embodiment. A fan-out back-to-back chip stacked packages 200 comprises a first chip 110, a second chip 120, an encapsulant 130, a plurality of vias 140, a first redistribution layer 150 and a second redistribution layer 160, which have the same structure as mentioned in the first embodiment.

The fan-out back-to-back chip stacked packages 200 further comprises a third chip 210 and a fourth chip 220. The third chip 210 has a third active surface 211, a third back surface 212 opposing to the third active surface 211 and a plurality of third sides 213. A plurality of third bonding pads 214 are disposed on the third active surface 211. The fourth chip 220 has a fourth active surface 221, a fourth back surface 222 opposing to the fourth active surface 221 and a plurality of fourth sides 223. A plurality of fourth bonding pads 224 are disposed on the fourth active surface 221. The fourth chip 220 is stacked on top of the third chip 210. Therein, a second die-attach film layer 271 is disposed between the third back surface 212 and the fourth back surface 222. In this embodiment, the third chip 210 and the fourth chip 220 are different from the first chip 110 and the second chip 120 in functions. Another chip stacked height from the third active surface 211 to the fourth active surface 221 is the same as the chip stacked height T2 from the first active surface 111 to the second active surface 121. The first redistribution layer 150 is further formed on the third active surface 211 and extended onto the first peripheral surface 131 to electrically connect the third bonding pads 214 to the corresponding first terminals 141. The second redistribution layer 160 is further formed on the fourth active surface 221 and extended onto the second peripheral surface 132 to electrically connect the fourth bonding pads 224 to the corresponding second terminals 142. Thus, multiple chips are side-by-side stacked in a fan-out back-to-back chip stacked package without a substrate can be achieved.

The above description of embodiments of this invention is intended to be illustrative but not limited. Other embodiments of this invention will be obvious to those skilled in the art in view of the above disclosure which still will be covered by and within the scope of the present invention even with any modifications, equivalent variations and adaptations.

1. A fan-out back-to-back chip stacked package comprising:
a first chip having a first active surface, a first back surface opposing to the first active surface and a plurality of first sides, wherein a plurality of first bonding pads are disposed on the first active surface;
a second chip having a second active surface, a second back surface opposing to the second active surface and a plurality of second sides, wherein a plurality of second bonding pads are disposed on the second active surface, wherein the second chip is stacked on the first chip having a die-attach film layer disposed between the first back surface and the second back surface, wherein a chip stacked height is formed from the first active surface to the second active surface;
an encapsulant encapsulating the first sides of the first chip and the second sides of the second chips simultaneously, wherein the encapsulant has a first peripheral surface expanding from the first active surface and a second peripheral surface expanding from the second active surface, wherein the thickness of the encapsulant is not greater than the chip stacked height in a manner that the first active surface and the second active surface are respectively exposed from two opposing faces of the encapsulant;
a plurality of vias disposed in the encapsulant, wherein each via has a first terminal and a second terminal, wherein the first terminals are exposed from the first peripheral surface and the second terminals are exposed from the second peripheral surface;
a first redistribution layer disposed on the first active surface and the first peripheral surface and configured to electrically connect the first bonding pads to the corresponding first terminals; and
a second redistribution layer disposed on the second active surface and the second peripheral surface and configured to electrically connect the second bonding pads to the corresponding second terminals.

2. The fan-out back-to-back chip stacked package as claimed in claim 1, wherein the vias are shaped as half cones.

3. The fan-out back-to-back chip stacked package as claimed in claim 1, further comprising:
a first passivation layer disposed above the first active surface and the first peripheral surface to cover at least one part of the first redistribution layer; and
a second passivation layer disposed above the second active surface and the second peripheral surface to cover at least one part of the second redistribution layer.

4. The fan-out back-to-back chip stacked package as claimed in claim 1, further comprising a plurality of solder balls disposed on the second redistribution layer.

5. The fan-out back-to-back chip stacked package as claimed in claim 1, further comprising:
a third chip having a third active surface, a third back surface opposing to the third active surface and a plurality of third sides, wherein a plurality of third bonding pads are disposed on the third active surface; and
a fourth chip having a fourth active surface, a fourth back surface opposing to the fourth active surface and a plurality of fourth sides, wherein a plurality of fourth bonding pads are disposed on the fourth active surface with a second die-attach film layer disposed between the third back surface and the fourth back surface, wherein a chip stacked height from the third active surface to the fourth active surface is the same as the chip stacked height from the first active surface to the second active surface;
wherein the first redistribution layer is further disposed on the third active surface and extended onto the first peripheral surface to electrically connect the third bonding pads to the corresponding first terminals, wherein the second redistribution layer is further disposed on the fourth active surface and extended onto the second peripheral surface to electrically connect the fourth bonding pads to the corresponding second terminals.

6. The fan-out back-to-back chip stacked package as claimed from claim 5, wherein the third chip and the fourth chip are different from the first chip and the second chip.

7. The fan-out back-to-back chip stacked package as claimed from claim 1, wherein the first chip and the second chip are identical chips.

8. The fan-out back-to-back chip stacked package as claimed from claim 1, wherein the die-attach film layer is disposed between the first chip and the second chip to form an intermediate buffer layer between the first chip and the second chip.

9. The fan-out back-to-back chip stacked package as claimed from claim 1, wherein the encapsulant is a single layer of molding compound having a substrate profile.

10. A method for manufacturing a fan-out back-to-back chip stacked package comprising the steps of:
disposing a plurality of first chips on a carrier plane of a temporary carrier, wherein each first chip has a first active surface, a first back surface opposing to the first active surface and a plurality of first sides, wherein a plurality of first bonding pads are disposed on the first active surface, wherein the temporary carrier is in wafer form or in panel form;
disposing a plurality of the second chips on the corresponding first chips, wherein each second chip has a second active surface, a second back surface opposing to the second active surface and a plurality of second sides, wherein a plurality of second bonding pads are disposed on the second active surface having a die-attach film layer disposed between the first back surface and the corresponding second back surface, wherein a chip stacked height is formed from the first active surface to the second active surface;
forming an encapsulant on the carrier plane, wherein the encapsulant encapsulates the first sides of the first chips and the second sides of the second chips simultaneously, wherein the encapsulant corresponding to each chip stacked package has a first peripheral surface expanding from each first active surface and a second peripheral surface expanding from each second active surface;
removing the temporary carrier, wherein the thickness of the encapsulant is not greater than the chip stacked height in a manner that the first active surface and the second active surface are respectively exposed from two opposing faces of the encapsulant;
disposing a plurality of vias in the encapsulant, wherein each via has a first terminal and a second terminal,
disposing a first redistribution layer and a second redistribution layer on the encapsulant, wherein the first redistribution layer is disposed on the first active surface and the first peripheral surface to electrically connect the first bonding pads to the corresponding first terminals, wherein the second redistribution layer is disposed on the second active surface and the second peripheral surface to electrically connect the second bonding pads to the corresponding second terminals; and
singulating the encapsulant to form a plurality of individual fan-out back-to-back chip stacked packages.

11. The method as claimed in claim 10, further comprising:
disposing a first passivation layer and a second passivation layer on the encapsulant, wherein the first passivation layer is disposed above the first active surface and the first peripheral surface to cover at least one part of the first redistribution layer, wherein the second passivation layer is formed over the second active surface and the second peripheral surface to cover at least one part of the second redistribution layer; and
disposing a plurality of solder balls on the second redistribution layer.

12. The method as claimed in claim 10, wherein the vias are shaped as half cones.

13. The method as claimed in claim 10, wherein the first chips and the second chips are identical chips.

14. The method as claimed in claim 10, wherein the die-attach film layer is disposed between the first chip and the second chip to form an intermediate buffer layer between the first chip and the second chip.

15. The method as claimed in claim 10, wherein the encapsulant is a single layer of molding compound having a substrate profile in wafer or panel form.

16. The method as claimed in claim 10, wherein the step of disposing the first redistribution layer and the second redistribution layer on the encapsulant includes disposing the first redistribution layer and the second redistribution layer on the encapsulant using a one time plating process.

17. The method as claimed in claim 16, wherein the step of disposing the first passivation layer and the second passivation layer on the encapsulant includes disposing the first passivation layer and the second passivation layer on the encapsulant using one time deposition process.
